(19) United States
(12) Patent Application Publication
(10) Pub. No.: US 2026/0315580 A1
(43) Pub. Date: Oct. 15, 2026

(54) THERAPEUTIC ENZYMES AND METHOD OF FORMULATING THEREOF BY SUBSTRATE SUBSTITUTION TO COMPENSATE FOR LOST SUBSTRATE ACTIVITY

(71) Applicant: Advantek Serum Laboratories Limited, Hong Kong (HK)

(72) Inventors: Chin-Pang Bennu YIU, Hong Kong (HK); Erik Johan PAUS, Brewster, MA (US)

(21) Appl. No.: 19/645,322

(22) Filed: Apr. 13, 2026

Related U.S. Application Data
(60) Provisional application No. 63/788,074, filed on Apr. 13, 2025.

(51) Int. Cl. A61K 38/51; A61K 31/05; A61K 31/198; A61K 47/08; A61K 47/10; A61K 47/20; A61K 47/22; A61K 47/42

(52) U.S. Cl. CPC A61K 38/51; A61K 31/05; A61K 31/198; A61K 47/08; A61K 47/10; A61K 47/20; A61K 47/22; A61K 47/42

(57) ABSTRACT

The present invention introduces the concept and methodology of substrate substitution to formulate substrate substitutes and co-formulants to be applied along with therapeutic enzymes for the compensation of one or more functions of the substrate that are removed due to the primary therapeutic effects. A substrate substitute for the enzymatic treatment prevents, reduces, or mitigates undesirable secondary effects and improves post-treatment tissue homeostasis following the modification or removal of a target substrate and its multitude of biological functions. In one aspect, the present invention provides a kit or a method for injections into an in vivo substrate such as a glycosaminoglycan in an intervertebral disc, spinal cord, or brain tissue as well as scar tissue, collagen-containing tissue, and aggrecan-containing tissue. The kit includes a therapeutic enzyme and at least one substrate substitute for the substrate targeted by the therapeutic enzyme, and optionally co-formulants for integrated effects.

### CROSS-REFERENCE TO RELEVANT APPLICATIONS

The present application claims priority from U.S. Provisional Patent Application Number 63/788,074 filed Apr. 13, 2025; the disclosure of which is incorporated herein by reference in its entirety.

### FIELD OF THE INVENTION

The present invention relates to therapeutic enzymes and, more particularly, to therapeutic enzymes combined with substitute substrate materials that can replace the functions of in vivo substrate material broken down by the therapeutic enzyme.

### BACKGROUND OF THE INVENTION

Degenerative disc disease, spinal cord injuries, and neurodegenerative disorders (e.g., traumatic brain injury) represent significant medical challenges with limited therapeutic options. Current treatments often involve systemic administration of drugs, which face barriers such as the blood-brain barrier (BBB) and blood-spinal cord barrier (BSCB), reducing efficacy and necessitating high doses that may lead to systemic side effects. Direct injection into the target tissues offers a promising alternative by bypassing these physiological barriers, delivering therapeutic agents precisely where they are needed. However, the success of such an approach depends on the identification of compounds that are safe, effective, and compatible with the delicate microenvironment of the CNS and spinal tissues.

Injection of enzymes that can break down unwanted tissue is a potential treatment for these conditions. Whereas enzymes are specific, occasionally the functions of the target substrate are vast and diverse. Removal of the substrate may, therefore, lead to unintended loss of functions and/or properties. Thus, there is a need in the art to minimize unwanted adverse effects that result from substrate removal by therapeutic enzyme removal treatments.

A predominant strategy adopted in enzymatic therapies is known as “enzyme replacement therapy” (ERT), in which a functional enzyme is administered to compensate for a missing or defective endogenous enzyme. ERT has been widely applied in metabolic and genetic disorders, particularly lysosomal storage diseases, examples of which include Gaucher disease, Fabry disease and Pompe disease.

While many therapeutic enzymes are replacement enzymes for patients lacking the native counterparts, as in the cases of glucocerebrosidase, alpha-galactosidase A, iduronidase, iduronate-2-sulfatase, N-acetylgalactosamine-6-sulfatase, arylsulfatase B, alpha-glucosidase, adenosine deaminase, cerliponase alfa, pancrelipase, lactase, and lysosomal acid lipase, biologics developers select a formulation that enables or optimizes the catalytic functions and restores metabolism to a normal level. It is not obvious to introduce replacement or substitution of lost substrate functions.

Where an enzyme modifies or removes a substrate to elicit a primary therapeutic effect, particularly with respect to substrates that perform diverse and multifunctional physiological roles, the desired therapeutic outcome is often coupled with the broad-spectrum depletion of endogenous substrates, thereby compromising essential or desirable functions and causing unwanted side-effects. Accordingly, there remains a need in the art to provide an improved methodology in enzyme therapies that prevents or mitigates the loss of functions due to depletion of substrates and reduces secondary outcomes of treatment.

### SUMMARY OF THE INVENTION

The present invention addresses the need for therapeutic enzyme formulation designs utilizing the “Substrate Substitution Approach.” As used herein, the term “substrate substitute” or “substrate substitution” relates to materials that substitute for the original substrate that has been acted upon by the therapeutic enzyme treatment, thus replacing some of the functions of the original substrate. In this manner, therapeutic enzyme treatments may be applied that minimize unwanted side effects that may otherwise occur. The substrate substitute is not impacted by the applied enzyme. Further, this approach may also be applied where gene or mRNA therapies are used and is not limited to enzyme protein formulations.

In a first aspect of the present invention, a method is provided for therapeutic enzyme treatment against a target substrate for a specific therapeutic enzyme that utilizes the “Substrate Substitution Approach”. The method comprises: (i) identifying or mapping biochemical functions of the target substrate apart from its coupled reaction with the specific therapeutic enzyme through function and pathway analysis and testing, through different means including but not limited to research or experimentation; (ii) selecting one or more substrate substitutes, wherein the one or more substrate substitutes replaces the biochemical functions of the target substrate, ; and (iii) simultaneously or sequentially applying the therapeutic enzyme and the one or more substrate substitutes. Particularly, the substrate substitutes are preferentially selected such that they are commonly known to possess strong safety profiles and known chemical and biological effects and that they do not interfere the action of the therapeutic enzyme.

In an embodiment of the first aspect of the present invention, the method further comprises selecting one or more co-formulants.

In a further embodiment, the one or more co-formulants is simultaneously or sequentially applied with the therapeutic enzyme and the one or more substrate substitutes.

In another further embodiment, the one or more co-formulants is chemically and biologically non-interactive with the target substrate, i.e. they are not involved in the coupled reaction of the substrate substitute with the specific therapeutic enzyme.

In a yet further embodiment, the one or more co-formulants are selected from glutathione, vitamin C, curcumin, coenzyme Q10 (CoQ10), or taurine.

In another embodiment, the therapeutic enzyme is provided in the form of a protein, a gene therapy, or an mRNA therapy.

In other embodiment, the therapeutic enzyme includes chondroitinase, heparinase, hyaluronidase, keratinase, aggrecanase, elastase/neutrophil elastase, matrix metalloproteinases (MMPS), or plasminogen activators.

In a second aspect of the present invention, a kit for injection into intervertebral disc, spinal cord, or brain tissue targeting chondroitin sulfate is provided. The injection kit is designed specifically against chondroitin sulfate metabolism, and is based on the above-mentioned “Substrate Substitution Approach”. The kit comprises a chondroitinase enzyme, a substrate substitute for chondroitin sulfate targeted by the chondroitinase enzyme selected from one or more of N-acetylcysteine and resveratrol, and instructions for the simultaneous or sequential application of the chondroitinase enzyme and the substrate substitute for the chondroitinase sulfate.

In an embodiment of the second aspect of the present invention. the concentration range of N-acetylcysteine is no higher than 400 mM, and the concentration range of resveratrol is no higher than 10 μM for the specified enzyme unit.

In a further embodiment, the chondroitinase is chondroitinase ABC.

In another embodiment, the kit further comprises one or more co-formulants and an instruction for the simultaneous or sequential application of the one or more co-formulants with the chondroitinase enzyme and the substrate substitute for the chondroitinase sulfate.

In a yet further embodiment, the co-formulants are selected from glutathione, vitamin C, curcumin, coenzyme Q10 (CoQ10), or taurine.

### BRIEF DESCRIPTION OF THE DRAWINGS

Embodiments of the invention are described in more details hereinafter with reference to the drawings, in which:

FIG. 1 tabulates the therapeutic potential of chondroitinase ABC (ChABC) across various pathological conditions, as evidenced in preclinical studies and clinical trials.

FIG. 2 shows the effect of N-acetylcysteine (NAC) concentration on the average enzymatic activity of chondroitinase ABC. Notably, 1.25 unit (U) per disc is currently used in vivo for canine disc herniation.

FIGS. 3A to 3B show the results of monitoring of the denaturation of ChABC. FIG. 3A shows the comparative intrinsic fluorescence spectroscopy results of chemically denatured ChABC against natural ChABC. FIG. 3B shows the urea denaturation of ChABC with and without N-acetylcysteine.

FIG. 4 shows the DCPIP test results indicating the antioxidant activity of NAC with and without ChABC.

FIG. 5 shows the difference in activity of ChABC at various concentrations of resveratrol.

FIG. 6 tabulates potential choices of natural compounds as co-formulants according to embodiments of the present invention, their respective recommended concentration range, and positive effects brought by the compounds. (note: to be reviewed)

### DETAILED DESCRIPTION

Prevailing enzymatic therapies, including but not limited enzyme replacement therapies (ERTs), the primary objective is to restore enzyme functions, and as such, the central concern is the control of dosage. However, as explained above and explained below in the case of chondroitin sulfate, this approach often overlooks the importance of the enzyme substrate itself, which carries a multitude of functionalities outside the specific substrate-enzyme reaction, and as such, by focusing only on the enzyme dosage without taking into account the potentially excessive depletion of substrates, this may cause adverse side effects.

In contrast, the substrate substitution approach provided in the present invention focuses on the reduction of secondary side effects and designing therapeutic enzyme formulations based on the substitution of lost substrate activities.

In the specific case of ERT, the substrate substitution approach remains to be relevant where substrates possess essential physiological functions, as it is designed to mitigate excessive modification or depletion of the substrate molecules while accounting for critical dosage effects.

More broadly, in light of recent surges in de novo protein design and other advancements, such as high-resolution single-cell and spatial atlases of tissues and deepened understanding of metabolic networks, therapeutic enzymes and substrate substitution strategies are poised to emerge as a growingly feasible and powerful means to address metabolic and other deficiencies.

Substrate substitution acts as precise tools to restore tissue homeostasis and go beyond conventional small-molecule and enzyme therapeutics that are directed to their targets and substrates and often provide only symptomatic relief.

The exemplary embodiments provided in the following sections revolve around the design of substrate substitute for chondroitin sulfate, the target substrate of chondroitinase ABC.

Chondroitinase ABC is a bacterial enzyme, classified as a glycosaminoglycan lyase, or glycosaminoglycanase, emphasizing its specificity for chondroitin sulfate and dermatan sulfate. It catalyzes the cleavage of the β-1,4 glycosidic bond between N-acetylgalactosamine (GalNAc) and glucuronic acid (GlcA) in these glycosaminoglycans (GAGs), producing unsaturated disaccharides through a β-elimination reaction. This endolytic mechanism disrupts the structure of chondroitin sulfate proteoglycans (CSPGs), which are critical components of the extracellular matrix (ECM) in various tissues, including the central nervous system (CNS), cartilage, and connective tissues.

Chondroitinase ABC activity is highly specific, targeting sulfated GAGs such as chondroitin sulfate A (CS-A), CS-B (dermatan sulfate), and CS-C. This specificity is crucial for its therapeutic applications, as it allows targeted modification of the ECM without affecting other GAGs nor proteins. The mechanism involves binding to the CS chain and cleaving it internally, reducing the length of the polysaccharide chains. This subsequently alters the properties in target sites.

Chondroitin sulfate, the target in vivo substrate of chondroitinase ABC, is a linear, sulfated GAG composed of repeating disaccharide units of GlcA and GalNAc, linked by alternating β-1,3 and β-1,4 glycosidic bonds. Each disaccharide unit is [GlcA-β-1,3-GalNAc-β-1,4-], forming a chain that can exceed 100 sugars, with variable sulfation patterns contributing to its functional diversity. CSPGs, which include these CS chains attached to a protein core, play roles in tissue structure, such as the nucleus populus in the intervertebral disc for shock absorption, cell signaling, and barrier formation, particularly in scar tissue of the brain and the spinal cord.

Since chondroitinase ABC’s interaction with its in vivo substrate is highly specific, with the enzyme’s active site recognizing the sulfated polysaccharide structure, by cleaving the β-1,4 bond, it depolymerizes the CS chains, transforming them into smaller fragments. This is particularly significant in pathological conditions where CSPGs form inhibitory barriers, such as in glial scars, making the enzyme a valuable tool for ECM remodeling. In the case of intervertebral disc herniation, this leads to the spinal cord decompression and pain relief.

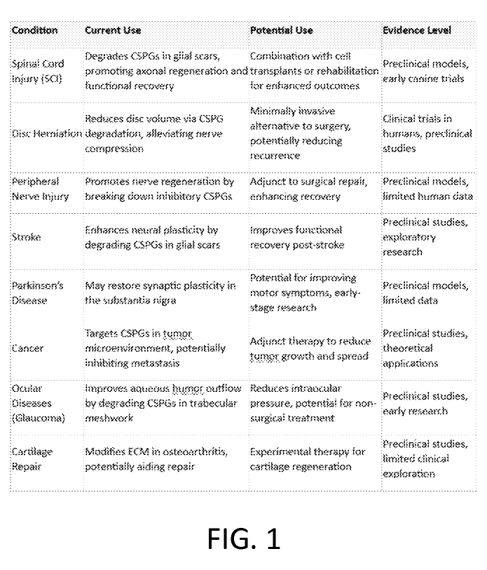

As described in greater detail in the Examples section below, and referring to FIG. 1, chondroitinase ABC has high therapeutic values through substrate digestion. Particularly, through the digestion of CSPGs in the glial scar, chondroitinase ABC promotes axonal sprouting and synaptogenesis, which is crucial in spinal cord injury recovery. Also, through degrading CSPGs, chondroitinase ABC is also able to reduce the volume of the nucleus pulposus, making chondroitinase ABC a feasible therapeutic option for disc herniation.

However, the multitude of functions carried by CSPGs imply that any CSPG removal by chondroitinase ABC may bring forth secondary outcomes, or side effects. As such, in the exemplary embodiments, the strategy adopted aims at the direct compensation of lost functions of CSPGs due to removal by chondroitinase ABC.

As used herein, the term “substrate substitute” or “substrate substitution” relates to materials that substitute for the original substrate that has been acted upon by the therapeutic enzyme treatment, thus replacing some of the functions of the original substrate. In this manner, therapeutic enzyme treatments may be applied to minimize unwanted side effects that may otherwise occur. The substrate substitute is not impacted by the applied enzyme. Further, this approach may also be applied where gene or mRNA therapies are used and is not limited to enzyme protein formulations.

As used herein, the term “co-formulant” relates to materials, mixtures, substances or ingredients that are neither active ingredients in the enzymatic reaction pathway, nor are they directly involved in the enzymatic reactions, but possess strong safety profiles and do not interact or interfere with the therapeutic enzymes or substrate substitutes, and carry beneficial therapeutical effects related to the complications or symptoms which therapeutical enzyme treatments aim to treat.

Accordingly, the present invention addresses the need for therapeutic enzyme formulation designs utilizing the “Substrate Substitution Approach”.

The invention is applicable to a broad range of therapeutic enzymes by providing various substrate substitutes. In one aspect, the present invention provides a kit for a composition targeting a target substrate of a therapeutic enzyme in a subject, comprising a therapeutic enzyme and a substrate substitute for the in vivo substrate targeted by the therapeutic enzyme. Instructions for the simultaneous application of the therapeutic enzyme, the substrate substitute as co-formulants for the target substrate of the therapeutic enzyme are also provided.

The therapeutic enzyme may be one or more of chondroitinase, heparinase, hyaluronidase, keratinase, aggrecanase, elastase/neutrophil elastase, matrix metalloproteinases (MMPS), or plasminogen activators; and the co-formulants may be one or more of resveratrol, vitamin C, curcumin, coenzyme Q10 (CoQ10), low-molecular-weight dextran, cross-linked hyaluronic acid, heparin or taurine.

This approach differs from routine techniques (e.g., excipient screening for stability) by requiring insight into substrate multifunctionality, which is increasingly critical for emerging modalities, including AI-designed enzymes and mRNA/gene therapies, where in situ enzyme expression can lead to prolonged or unanticipated substrate depletion and its associated secondary effects.

Certain exemplary embodiments are provided in the below Example section, with a particular focus on the use of chondroitinase ABC (ChABC) in tandem with various substrate substitutes or co-formulants, and data and results supporting the simultaneous use thereof.

### EXAMPLES

Prominent examples in which the direct application of enzyme target degenerative disc disease, spinal cord injuries, and neurodegenerative disorders (e.g., traumatic brain injury). Current treatments often involve systemic administration of drugs, which face barriers such as the blood-brain barrier (BBB) and blood-spinal cord barrier (BSCB), reducing efficacy and necessitating high doses that may lead to systemic side effects.

Direct injection into the target tissues offers a promising alternative bypassing these physiological barriers, delivering therapeutic agents precisely where they are needed. However, the success of such an approach depends on the identification of compounds that are safe, effective, and compatible with the delicate microenvironment of the CNS and spinal tissues.

Injection of enzymes that can break down unwanted tissue is a potential treatment for these conditions. While many therapeutic enzymes are replacement enzymes for patients lacking the native counterparts, as in the cases of glucocerebrosidase, alpha-galactosidase A, iduronidase, iduronate-2-sulfatase, N-acetylgalactosamine-6-sulfatase, arylsulfatase B, alpha-glucosidase, adenosine deaminase, cerliponase alfa, pancrelipase, lactase, and lysosomal acid lipase, biologics developers select a formulation that enables or optimizes the catalytic functions and replaces the lost functions.

An example of a therapeutic enzyme treatment involves the use of chondroitinase ABC. Chondroitinase ABC is a bacterial enzyme derived from Proteus vulgaris that has garnered significant attention in biomedical research due to its ability to degrade glycosaminoglycans (GAGs), specifically chondroitin sulfate proteoglycans (CSPGs) and dermatan sulfate.

CSPGs are complex macromolecules composed of a protein core with covalently attached chondroitin sulfate (CS) chains, which are is a linear, sulfated GAG composed of repeating disaccharide units of glucuronic acid (GlcA) and N-acetylgalactosamine (GalNAc), linked by alternating β-1,3 and β-1,4 glycosidic bonds. Each disaccharide unit is [GlcA-β-1,3-GalNAc-β-1,4-], forming a chain that can exceed 100 sugars, with variable sulfation patterns contributing to its functional diversity. These molecules are abundant in the extracellular matrix (ECM) of various tissues, particularly in the central nervous system (CNS), cartilage, and connective tissues.

Chondroitinase ABC catalyzes the cleavage of the β-1,4-glycosidic bonds within chondroitin sulfate chains, effectively depolymerizing them into smaller disaccharides through a β-elimination reaction. This enzymatic action targets both chondroitin sulfate A (CS-A), chondroitin sulfate B (CS-B, also known as dermatan sulfate), and chondroitin sulfate C (CS-C), making it a broad-spectrum chondroitin lyase. It also breaks down hyaluronic acid, but it does not break down heparin.

The relationship between chondroitinase ABC and its in vivo substrate, chondroitin sulfate, is, therefore, highly specific yet versatile. The enzyme’s active site recognizes the sulfated polysaccharide structure of CS chains, binding to them and facilitating their degradation through an endolytic mechanism. This process disrupts the structural integrity of CSPGs, which play a critical role in maintaining tissue architecture and regulating cellular processes. In the context of pathology, CSPGs are often overexpressed or dysregulated, forming inhibitory barriers that impede tissue repair and regeneration. By breaking down these inhibitory CS chains, chondroitinase ABC alters the ECM microenvironment, unlocking potential therapeutic benefits. This is particularly significant in pathological conditions where CSPGs form inhibitory barriers, such as in glial scars, making the enzyme a valuable tool for ECM remodeling. In the case of intervertebral disc herniation, this leads to spinal cord decompression and pain relief.

The therapeutic potential of chondroitinase ABC spans several conditions, with robust evidence from preclinical studies and emerging clinical trials. Refer to FIG. 1 for a detailed breakdown.

While many therapeutic enzymes are replacement enzymes, the bacterial enzyme, chondroitinase ABC acts through the actions of substrate digestion. Two areas of therapeutic applications are particularly noteworthy.

Spinal Cord Injury (SCI): Extensive research demonstrates chondroitinase ABC’s efficacy in degrading CSPGs in the glial scar, promoting axonal sprouting and synaptogenesis. Preclinical models show improved motor and sensory recovery, with recent canine trials suggesting feasibility for human applications.

Disc Herniation: The enzyme’s ability to reduce the volume of the nucleus pulposus by degrading CSPGs offers a non-surgical treatment option. Based on chemonucleolysis, chondroitinase ABC alleviates pain and cause little side-effects, unlike earlier chemonucleolytic agents, such as collagenase and papain, which cause unwanted digestion of proteins.

Additionally, emerging research suggests applications in peripheral nerve injury, stroke, and Parkinson’s disease, where CSPGs inhibit regeneration or plasticity. For cancer, studies indicate CSPGs’ role in metastasis, with chondroitinase ABC potentially disrupting tumor progression. In glaucoma, degrading CSPGs in the trabecular meshwork could improve fluid dynamics, as explored in preclinical models.

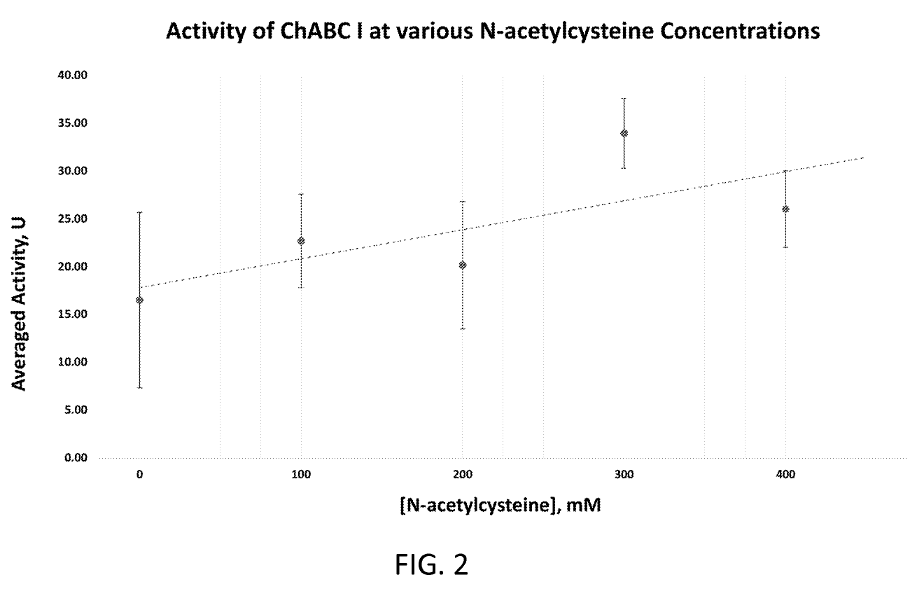

Dosage: Since the enzyme is used at or near the central nervous system (CNS), the dosage required is better reduced where desirable. An improved formulation will enhance the enzymatic activity, reduce the needed dosage, and remain safe for use at and/or near the CNS. See, for example, FIG. 2 for the effects of NAC concentrations on the average enzymatic activity.

However, despite its promise, chondroitinase ABC faces significant general challenges that limit its clinical translation.

Stability: The effectiveness of the enzyme is greatly influenced by its thermodynamic stability. It is preferred to have a formulation that enhances or preserves the stabilities of the enzyme structure as well as the enzymatic activity over periods of storage.

Delivery: To precisely deliver the enzyme to pathological sites will lower risks of off-target effects and subsequently the therapeutic effects.

Through preserved activity and stability, the formulation described herein as an example addresses the first two general issues. In general, the co-formulant with chondroitinase ABC will preferably be safe for use at and/or near the CNS. This invention could generally maintain the stability and/or pharmacokinetics of the biologics for applications like SCI and disc herniation.

In addition, excessive depletion of CS or CSPGs is also not ideal, as they are not merely inhibitory as in certain pathological contexts. As CS scavenges reactive oxygen species (ROS), chelates metal ions including calcium, and modulates inflammation, its depletion could unmask secondary pathologies, such as oxidative stress or ectopic calcification, particularly in chronic degenerative settings.

Example 1 below expands its utility into the realm of CNS and spinal therapies, leveraging its biochemical properties to address unmet clinical needs in degenerative, traumatic, and inflammatory conditions affecting these regions, by introducing NAC as the substrate substitute and/or replacement agent for CS. In addition, other substrate substitutes or replacement agents for CS are also discussed herewith in further Examples below.

Example 1 – NAC as a Substrate Substitute or Replacement

N-acetylcysteine (NAC), a derivative of the amino acid cysteine, has been widely recognized for its mucolytic, antioxidant, and anti-inflammatory properties, traditionally used in the treatment of acetaminophen overdose and respiratory conditions, and is thus a well-established pharmacological compound and an excipient, with proven in vivo safety. In one aspect, NAC in applied with chondroitinase ABC or before or after application of chondroitinase ABC for direct injection into a site selected for ChABC therapeutic enzyme treatment. For example, NAC may be applied into an intervertebral disc, spinal cord, or brain along with chondroitinase ABC, as a substrate substitute or replacement agent for chondroitin sulfate. As used herein, the term “substrate substitute” relates to a material, here NAC, that substitutes for some of the lost functions of the in vivo substrate that may be affected by the chondroitinase ABC. For example, loss of chondroitin sulfate, the in vivo target substrate of ChABC, may result in inflammation or oxidation. NAC or other substrate substitutes having anti-inflammatory or antioxidative effects replaces or “substitutes” for the lost functions of the chondroitin sulfate substrate.

NAC is uniquely suited for this purpose due to its multifaceted pharmacological profile. Qualitatively, NAC acts as an antioxidantby replenishing glutathione levels, a critical scavenger of reactive oxygen species (ROS) implicated in oxidative stress—a common pathological feature of disc degeneration, spinal cord injury, and brain disorders. Its anti-inflammatory effects, mediated through the inhibition of pro-inflammatory cytokines such as TNF-α and IL-6, further enhance its therapeutic potential. Additionally, NAC’s mucolytic properties may facilitate the breakdown of extracellular matrix debris in degenerative discs, improving tissue health and drug diffusion. As an excipient, NAC improves co-administered biologicals through oxidative stability, enhanced solubility, and reduction of local toxicity at the injection site, making it an attractive adjunct in combination therapies. NAC as a substitute substrate for chondroitin to substitute, replace, and/or supplement the effects of chondroitin sulfates.

Quantitatively, NAC’s efficacy is supported by its established safety profile and pharmacokinetic advantages. Currently, there are 582 clinical trials on NAC listed in clinicaltrials.gov (as of Q12025). A typical dosage is approximately 800 mg per day for oral administration. Clinical studies of intravenous NAC administration have demonstrated tolerability at doses up to 150-300 mg/kg, with peak plasma concentrations reaching 300–500 µM within hours, suggesting its potential for safe local delivery at therapeutic levels. Preliminary in vitro studies indicate that NAC concentrations of 10–50 mM, when applied directly to cultured disc cells or neural tissue, significantly reduce ROS levels. Specifically, it attenuates oxidative stress‐mediated cell viability loss induced by dimethyl sulfoxide in cryopreservation of human nucleus pulposus cells. These findings support the feasibility of clinical use as a drug co-formulant for CNS uses.

As mentioned, NAC as a co-formulant that enhances chondroitinase ABC lytic activity will potentially allow concentration optimization and dosage reduction. NAC could be included in protein formulations to maintain stability during storage and delivery. Moreover, combining NAC with the enzyme may bring synergistic effects through leveraging its antioxidant properties to protect against oxidative stress at the injection site, enhancing therapeutic outcomes.

NAC is favorable for formulation design as it could be used in injectable solutions or gels for sustained release, ensuring prolonged stability and local action in the intervertebral disc, spinal cord, or brain.

Below are investigations on the stability of ChABC, and the effects of its co-administration with NAC and other co-formulants.

The ChABC used in the Examples was manufactured in-house using a proprietary protocol based on native extraction from Proteus vulgaris. However, recombinant ChABC, as well as ChABC variants containing mutations in the wild-type amino acid sequence, are also applicable.

1.1 Methods

1.1.1 Enzymatic Activity Assay

ChABC activity was evaluated spectrophotometrically at 232 nm by monitoring the formation of unsaturated disaccharides from the substrate. Enzyme stock (10 U) was diluted in saline to a final concentration of 0.6 U. The reaction mixture contained 1% chondroitin sulfate C in 0.05 mM Tris-HCl buffer, pH 8.0. Assays were performed in the presence or absence of co-formulants to determine their potential to enhance or interfere with enzymatic activity.

1.1.2 Stability Assay

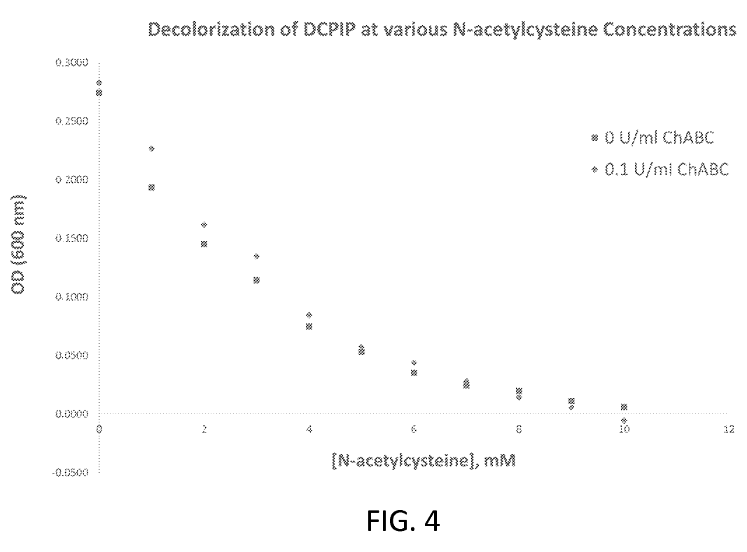

Chemical denaturation of ChABC was monitored by intrinsic fluorescence spectroscopy using a Thermo Scientific Varioskan LUX Multimode Microplate Reader. Excitation was set at 283 nm and emission at 320 nm to capture maximum intrinsic fluorescence signals (FIG. 4A). The assay was performed with 1.5 μM ChABC.

1.1.3 Antioxidant Assay

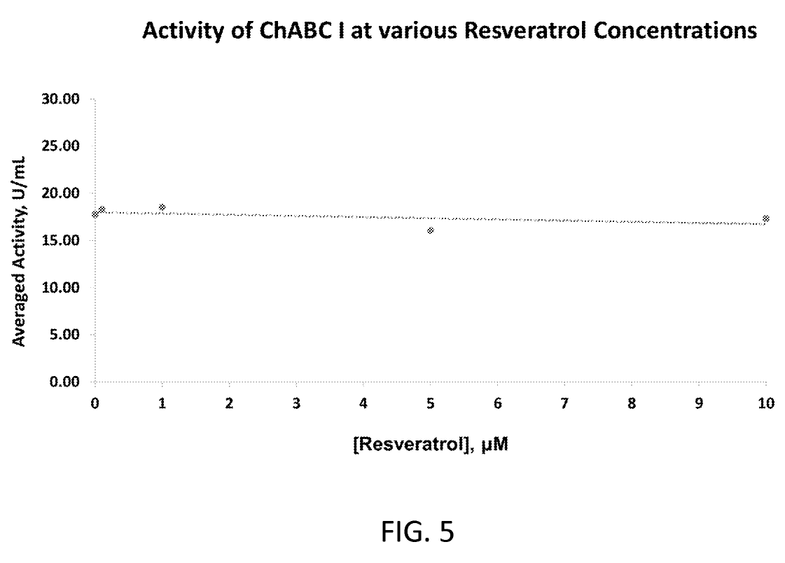

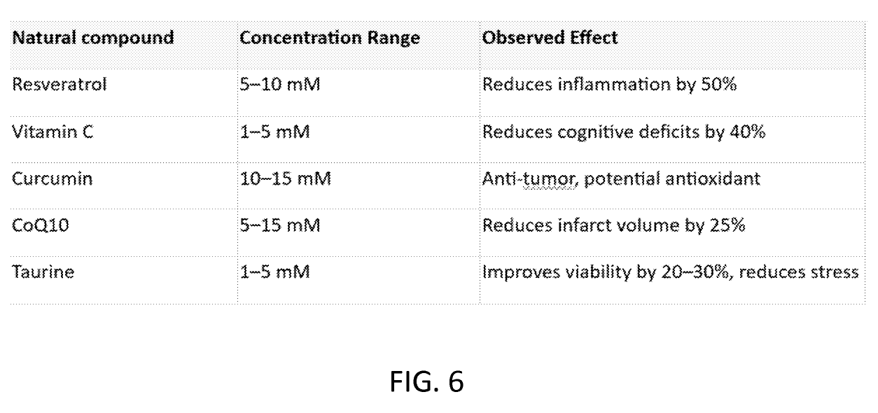

1 ml of 0.1 mM 2,6-Dichloroindophenol sodium salt hydrate solution was mixed with 1 ml of NAC in saline at various concentrations. Reductions in absorbance at 600 nm were measured immediately and after 5 minutes using a Thermo Evolution 201 UV-Vis Spectrophotometer, and the result is shown in FIG. 5.

1.2 Results

The average ChABC activity increases with NAC concentrations in the range of 0 to 400 mM (see FIG. 2) in repeated experiments, which would cover possible therapeutic-relevant levels, such as 50 mM. At 300-400 mM NAC, the activity rises by 1.5- to 2-fold.

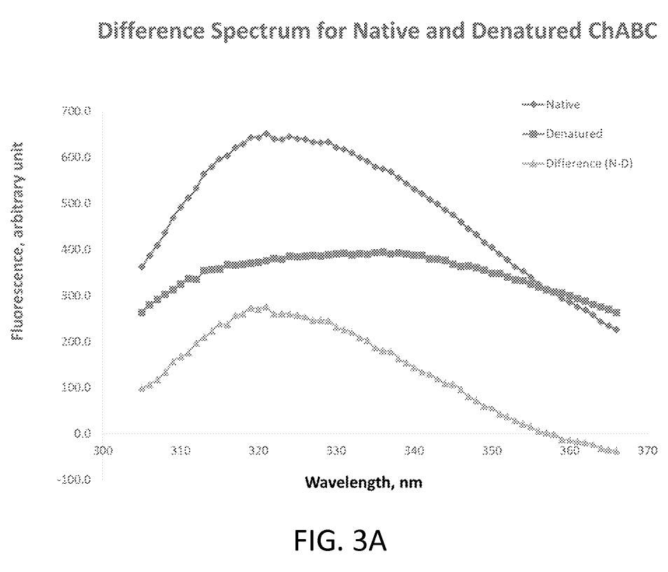

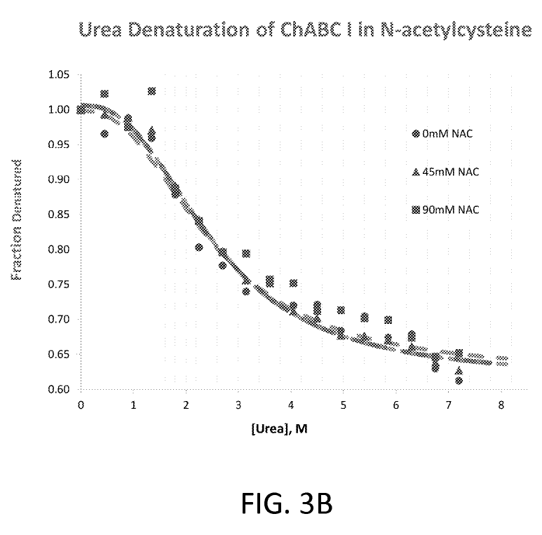

Chaotropic denaturation using urea was monitored using fluorescence spectroscopy. The chemical stability of ChABC I is preserved with transition mid-point staying at approximately 1.9 M urea (see FIG. 3B).

As shown in FIG. 4, ChABC did not impair NAC antioxidant capacity in the DCPIP test for antioxidant activity. While the antioxidant activity of NAC is preserved in the presence of ChABC, this compatibility supports co-formulation without compromising either component.

As observed in the results shown in FIG. 5, the activity of ChABC is maintained at increasing resveratrol levels in the range of 0 to 10 μM, thereby supporting the incorporation of resveratrol as co-formulant does not compormise the activity of ChABC.

Example 2 - Reservatrol as a Substrate Substitute or Replacement

Reservatrol is a common plant polyphenol. It is a common antioxidant that shows free-radical scavenging, Nrf2 activation, and anti-inflammatory effects. It has cartilage-protective potential in osteoarthritis models by reducing oxidative damage and inflammation.

In the context of chondroitinase ABC treatment, oxidative stress and inflammation are contributors to the intervertebral disc degeneration, resveratrol is shown to exert anabolic effects, as confirmed by radiological, biochemical, and histological analyses in a rabbit model of intervertebral disc degeneration. Hence this makes it suitable for compensating antioxidant, anti-inflammatory and anti-degeneration effects of chondroitin sulphate.

Like NAC, resveratrol could be combined with proteins to enhance formulation stability and efficacy, particularly for therapies targeting at or near the CNS. Proposed strategies include using concentrations of 5–10 μM to maintain stability. Combining resveratrol with proteins like neurotrophins could leverage its antioxidant properties to protect against oxidative stress at the injection site, potentially in injectable solutions or gels for sustained release. In CNS injections, where oxidative stress is elevated, resveratrol’s role as an excipient may ensure the efficacy of biologics during storage and delivery.

Notably, resveratrol’s intrathecal use in spinal cord injury models shows promise. While most studies are in animal models, resveratrol may reduce neuroinflammation via intrathecal injection.

Example 3 - Other Substrate Substitutes or Replacements

Other substrate substitutes include naturally occurring antioxidants and anti-inflammatory compounds, which are suitable for direct injection into the intervertebral disc, spinal cord, and brain.

Examples of such compounds are glutathione, vitamin C, curcumin, coenzyme Q10 (CoQ10), and taurine. Their strong safety profile for direct central nervous system delivery makes them promising candidates as co-formulants for protein biologics.

FIG. 7 below shows the properties of various potential co-formulants at particular concentrations.

Example 4 - Additional Co-formulant to Prevent or Reduce Calcification

Chondroitin sulphate binds metal ions including calcium, which plays a role in disc mineralization and calcification. By the substitute substrate approach, a calcium binding agent can be used. For example, sodium citrate is also safe and preferred to sodium phosphate alone, the latter of which does not bind calcium ions. Therefore, in addition to an ChABC + NAC (and/or other antioxidants) formulation, a further improvement may be ChABC + NAC in sodium citrate containing buffer.

Example 5 - Other enzyme and substrate substitutes

Various other enzymes have therapeutic applications in vivo and can similarly be co-administered or sequentially administered with a substrate substitute. For example, other chondroitin sulfate targeting enzymes can be co-administered with the substrate substitutes (e.g., NAC) described above. Alternatively, other enzymes that are applied in vivo and their in vivo target substrates for therapeutic treatment are:
1. Heparanase (human or recombinant form) Target substrate: Heparan sulfate proteoglycans (HSPGs) in the ECM and basement membrane.
2. Matrix Metalloproteinases (MMPs) Target substrate: Degrade various ECM components including collagens, aggrecan, and fibronectin.
3. Aggrecanase (ADAMTS family enzymes): Target substrate: Aggrecan, a major proteoglycan in cartilage and IVD.
4. Plasminogen Activators (e.g., tPA, uPA): Target substrate: Fibrin and matrix components involved in scarring.
5. Elastase and Neutrophil Elastase Inhibitors: Target substrate: Elastin and certain ECM proteins.

Various substrate substitutes can be co-administered or sequentially administered (before or after) with these therapeutic enzymes. For example, alpha lipoic acid (ALA), a naturally occurring organosulfur compound, derived from octanoic acid, contains a dithiolane ring that gives it potent redox (antioxidant) activity. As such, ALA can scavenge reactive oxygen species (ROS). In its reduced form, dihydrolipoic acid (DHLA), also regenerates other antioxidants (e.g., glutathione, vitamin C, vitamin E). The antioxidant capacity of ALA suppresses ROS-induced activation of ECM-degrading enzymes, such as MMPs, elastase, and collagenase.

Polyphenols (e.g., EGCG from green tea, resveratrol) may be used to bind to and inhibit MMPs, elastase, and collagenase. These may be used to modulate inflammation and reduce ECM degradation.

### REFERENCES

The following references, the disclosures of which are incorporated herein by reference in their entirety, providing background information regarding chondroitinase ABC, glutathione, NAC, resveratrol, calcium binding, and the use of chondroitinase ABC in spinal cord and disc injuries.

NAC as an antioxidant and anti-inflammatory agent:

N‐acetylcysteine attenuates oxidative stress‐mediated cell viability loss induced by dimethyl sulfoxide in cryopreservation of human nucleus pulposus cells https://www.ncbi.nlm.nih.gov/pmc/articles/PMC9799083;

N-Acetylcysteine and Its Immunomodulatory Properties in Humans and Domesticated Animals https://www.mdpi.com/2076-3921/12/10/1867;

Excessive reactive oxygen species are therapeutic targets for intervertebral disc degeneration https://pubmed.ncbi.nlm.nih.gov/26542776/;

The Mechanism and Inflammatory Markers Involved in the Potential Use of N-acetylcysteine in Chronic Pain Management https://www.mdpi.com/2075-1729/14/11/1361;

Chondroitin sulphates have antioxidant and anti-inflammatory activities :

Antioxidant Activity of Chondroitin Sulfate doi: 10.1016/S1054-3589(05)53020-5;

Immunomodulatory and anti-inflammatory effects of chondroitin sulphate doi:10.1111/j.1582-4934.2009.00826.x;

Degrading products of chondroitin sulfate can induce hypertrophy-like changes and MMP-13/ADAMTS5 production in chondrocytes https://www.nature.com/articles/s41598-019-52358-4;

Disc degenerative and inflammatory effects of chABC:

Changes in Intervertebral Disc Properties after Intradiscal Injection of Condoliase for Painful Lumbar Disc Herniation doi: 10.2176/jns-nmc.2023-0302;

Inflammatory Cytokine and Catabolic Enzyme Expression in a Goat Model of Intervertebral Disc Degeneration doi:10.1002/jor.24639

Therapeutic uses (a partial list)

Research and Application of Chondroitin Sulfate/Dermatan Sulfate-Degrading Enzymes(https://www.frontiersin.org/journals/cell-and-developmental-biology/articles/10.3389/fcell.2020.560442/full)

Recent advances in the therapeutic uses of chondroitinase ABC (https://pubmed.ncbi.nlm.nih.gov/31398353/)

Chondroitinase: A promising therapeutic enzyme (https://pubmed.ncbi.nlm.nih.gov/25319196/)

Chondroitinase as a therapeutic enzyme: Prospects and challenges (https://www.sciencedirect.com/science/article/abs/pii/S0141022923001564)

Chondroitinase ABC I as a novel candidate for reducing damage in spinal cord injury (https://www.sciencedirect.com/science/article/abs/pii/B9780128224984000257)

Chondroitinase ABC Enzyme: A Potential Treatment Option for Spinal Cord Injury (https://pmc.ncbi.nlm.nih.gov/articles/PMC6259299/)

The role of chondroitinase as an adjuvant to peripheral nerve repair (https://pubmed.ncbi.nlm.nih.gov/25766067/)

Glutathione protects human nucleus pulposus cells from cell apoptosis and inhibition of matrix synthesis (https://pubmed.ncbi.nlm.nih.gov/24409809/)

Rescue of nucleus pulposus cells from an oxidative stress microenvironment via glutathione-derived carbon dots to alleviate intervertebral disc degeneration (https://jnanobiotechnology.biomedcentral.com/articles/10.1186/s12951-024-02683-2)

Glutathione: A Samsonian life-sustaining small molecule that protects against oxidative stress, ageing and damaging inflammation (https://www.frontiersin.org/journals/nutrition/articles/10.3389/fnut.2022.1007816/full)

Lipid Peroxidation, Reduced Glutathione, and Glutathione Peroxidase Levels in Intervertebral Discs of Patients with Lumbar Degenerative Disc Disease (https://www.ncbi.nlm.nih.gov/pmc/articles/PMC11131429)

Effect of Glutathione Augmentation on Lipid Peroxidation after Spinal Cord Injury (https://www.liebertpub.com/doi/10.1089/08977150260139138)

Use of Cells, Supplements, and Peptides as Therapeutic Strategies for Modulating Inflammation after Spinal Cord Injury: An Update (https://pmc.ncbi.nlm.nih.gov/articles/PMC10531377/#sec3-ijms-24-13946)

The Antioxidant Role of Glutathione and N-AcetylCysteine Supplements and Exercise-Induced Oxidative Stress (https://www.tandfonline.com/doi/pdf/10.1186/1550-2783-2-2-38)

Intrathecal resveratrol reduces inflammation and improves functional recovery after spinal cord injury in rats (https://jneuroinflammation.biomedcentral.com/articles/10.1186/s12974-017-0892-5)

Ascorbic acid infusion prevents progressive brain damage during reperfusion after focal cerebral ischemia (https://www.sciencedirect.com/science/article/pii/S0304394003009867)

Curcumin-loaded polymeric micelles for brain delivery: preparation, characterization and in vitro evaluation (https://www.sciencedirect.com/science/article/pii/S037851731830297X)

Intracerebral administration of coenzyme Q10 reduces infarct volume after transient focal cerebral ischemia in rats (https://journals.lww.com/neuroreport/abstract/2004/08180/intracerebral_administration_of_coenzyme_q10.17.aspx)

Intracerebral microinjection of taurine increases sleep in cats (https://www.sciencedirect.com/science/article/pii/000689938390242X)

The Binding of Cations by Chondroitin Sulfate (https://dm5migu4zj3pb.cloudfront.net/manuscripts/103000/103573/JCI57103573.pdf

Effects of chondroitin sulphates on mineralization in vitro (doi: 10.1042/bj1030382)

A seminal perspective on the role of chondroitin sulfate in biomineralization (doi: 10.1016/j.carbpol.2023.120738)

The Role of Sulfated Protein-Polysaccharides in Calcification (https://journals.lww.com/clinorthop/citation/1964/00350/The_Role_of_Sulfated_Protein_Polysaccharides_in.17.aspx)

Experimental determination of the kinetics of calcium-binding with chondroitin sulphate and the effects of uric acid on this process (https://link.springer.com/article/10.1007/BF00260940)

Supplemented Chondroitin Sulfate and Hyaluronic Acid Suppress Mineralization of the Chondrogenic Cell Line, ATDC5. (doi: 10.1248/bpb.b17-00059).

1. A method for optimizing therapeutic enzyme treatment against a target substrate for a specific therapeutic enzyme, comprising:
identifying or mapping biochemical functions of the target substrate independently of its coupled reaction with the specific therapeutic enzyme by performing functional and pathway testing and analysis;
selecting one or more substrate substitutes, wherein the one or more substrate substitutes replaces the biochemical functions of the target substrate; and
simultaneously or sequentially applying the therapeutic enzyme and the one or more substrate substitutes;
wherein the one or more substrate substitutes are independent from the coupled reaction of the target substrate with the specific therapeutic enzyme.

2. The method of claim 1, further comprising selecting one or more co-formulants.

3. The method of claim 2, wherein the one or more co-formulants is simultaneously or sequentially applied with the therapeutic enzyme and the one or more substrate substitutes.

4. The method of claim 2, wherein the one or more co-formulants are independent from the coupled reaction of the target substrate with the specific therapeutic enzyme.

5. The method of claim 2, wherein the one or more co-formulants are selected from glutathione, vitamin C, curcumin, coenzyme Q10 (CoQ10), or taurine.

6. The method of claim 1, wherein the therapeutic enzyme is provided in the form of a protein, a gene therapy, or an mRNA therapy.

7. The method of claim 1, wherein the therapeutic enzyme includes chondroitinase, heparinase, hyaluronidase, keratinase, aggrecanase, elastase/neutrophil elastase, matrix metalloproteinases (MMPS), or plasminogen activators.

8. A kit for injection into intervertebral disc, spinal cord, or brain tissue targeting chondroitin sulfate, comprising:
a chondroitinase enzyme;
a substrate substitute for chondroitin sulfate targeted by the chondroitinase enzyme selected from one or more of N-acetylcysteine and resveratrol;
instructions for the simultaneous or sequential application of the chondroitinase enzyme and the substrate substitute for the chondroitinase sulfate.

9. The kit according to claim 8, wherein the concentration range of N-acetylcysteine is no higher than 400 mM, and the concentration range of resveratrol is no higher than 10 µM for the specified enzyme unit.

10. The kit according to claim 9, wherein the chondroitinase is chondroitinase ABC.

11. The kit according to claim 9, further comprising one or more co-formulants acts in an integrated manner with the substrate substitutes, and an instruction for the simultaneous or sequential application of the one or more co-formulants with the chondroitinase enzyme and the substrate substitute for the chondroitinase sulfate.

12. The kit according to claim 11, wherein the one or more co-formulants are selected from glutathione, vitamin C, curcumin, coenzyme Q10 (CoQ10), or taurin.
